(19) United States
(12) Patent Application Publication
(10) Pub. No.: US 2012/0112249 A1
(43) Pub. Date: May 10, 2012

(54) HIGH PERFORMANCE SEMICONDUCTOR DEVICE AND METHOD OF FABRICATING THE SAME

(75) Inventors: Haizhou Yin, Poughkeepsie, NY (US); Huilong Zhu, Poughkeepsie, NY (US); Zhijiong Luo, Poughkeepsie, NY (US)

(73) Assignee: INSTITUTE OF MICROELECTRONICS, CHINESE ACADEMY OF SCIENCES, BEIJING (CN)

(21) Appl. No.: 12/995,030

(22) PCT Filed: Jun. 25, 2010
(86) PCT No.: PCT/CN10/74469

§ 371 Date: Dec. 1, 2010

(30) Foreign Application Priority Data
Dec. 4, 2009 (CN) 200910242098.0

(51) Int. Cl. H01L 29/772; H01L 21/336

(52) U.S. Cl. 257/288; 438/308; 257/E21.409; 257/E29.242

(57) ABSTRACT

A method for fabricating a semiconductor device employs the way of first performing thermal annealing to the source/drain regions and then forming an ion-implanted region, such as a retrograde well. The method comprises the steps of: removing said dummy gate so as to expose said dummy gate dielectric layer and form an opening; performing ion implantation on the substrate from the opening to form an ion-implanted region; removing the dummy gate dielectric layer; performing thermal annealing to activate the dopants of the ion-implanted region; and depositing a new gate dielectric layer and a new metal gate in the opening in sequence, wherein the formed new gate dielectric layer covers the substrate and the inner walls of the sidewall spacers. By means of the present invention, it is possible to avoid inappropriately introducing the dopants of the ion-implanted region into the source region and the drain region, such that the profile of the ion-implanted region does not overlap with the dopants of the source/drain regions, thereby avoiding increasing the band-to-band leakage current in a MOSFET device. As a result, the performance of the device is improved.

### FIELD OF THE INVENTION

The present invention generally relates to a semiconductor device and its fabrication method. More specifically, it relates to a semiconductor device that avoids introduction of inappropriate dopants into the source and drain regions from the ion-implanted region, especially the retrograde well region of the substrate, as well as the fabrication method thereof.

### DESCRIPTION OF THE PRIOR ART

With the development of the semiconductor industry, integrated circuits having higher performance and more powerful function require higher density of elements. Thus, the size of the components needs to be further reduced. Accordingly, in order to improve the performance of a MOSFET (metal oxide semiconductor field effect transistor) device, the length of the gate of the MOSFET device needs to be further reduced. However, as the length of the gate reduces continuously till it is close to the width of the depletion layer of the source and the drain, e.g. less than 40 nm, a serious short channel effect (SCE) will be produced, thereby degrading the performance of the device adversely and causing difficulty in production of large scale integrated circuits. Therefore, it has become a crucial problem in production of large scale integrated circuits as to how the short channel effect can be reduced and effectively controlled. A retrograde well that can reduce the short channel effect is described in Thompson S, et. al., “MOS Scaling: Transistor Challenges for the 21^{st} Century”, Intel Technology Journal Q3'98, pp. 1-19. Since forming a retrograde well in the substrate will usually inappropriately introduce the dopants into the source region and the drain region, and the profile of the retrograde well overlaps with the dopants of the source/drain regions, the band-to-band leakage current and the source-drain junction capacitance in the MOSFET device will increase, resulting in degradation of the performance of the device.

Hence, in order to improve production of a high performance semiconductor device, a semiconductor device and its fabrication method are needed to avoid introduction of inappropriate dopants into the source and drain regions when forming an ion-implanted region, especially a retrograde well region in the substrate.

### SUMMARY OF THE INVENTION

In order to solve the above-mentioned problem, the present invention provides a method for fabricating a semiconductor device which comprises the steps of: a) providing a substrate; b) forming on the substrate a source region, a drain region, a gate stack provided on the substrate and between the source region and the drain region, sidewall spacers formed at the sidewalls of the gate stack, and an interlayer dielectric layer covering the source region and the drain region, said gate stack comprising a dummy gate dielectric layer and a dummy gate; c) removing said dummy gate so as to expose said dummy gate dielectric layer and form an opening; d) ion implanting the substrate from the opening to form an ion-implanted region; e) removing the dummy gate dielectric layer; f) performing thermal annealing to activate the dopants in the ion-implanted region; g) depositing a gate dielectric layer and a metal gate in the opening, wherein the gate dielectric layer covering the inner walls of the sidewall spacers. Especially, said step d) is used to form a retrograde well.

In addition, the semiconductor device can be fabricated by such a substitute method that comprises the steps of: a) providing a substrate; b) forming on the substrate a source region, a drain region, a gate stack provided on the substrate and between the source region and the drain region, sidewall spacers formed at the sidewalls of the gate stack, and an interlayer dielectric layer covering the source region and the drain region, said gate stack comprising a dummy gate dielectric layer and a dummy gate; c) removing said dummy gate and said dummy gate dielectric layer, so as to expose said substrate and form an opening; d) ion implanting the substrate from the opening to form an ion-implanted region; e) performing thermal annealing to activate the dopants in the ion-implanted region; f) depositing a gate dielectric layer and a metal gate in the opening, wherein the gate dielectric layer covering the inner walls of the sidewall spacers. Especially, said step d) is used to form a retrograde well.

According to another aspect of the present invention, a semiconductor device is also provided, which comprises: a substrate, a source region and a drain region formed on the substrate, a gate stack formed on the substrate and between the source region and the drain region, sidewall spacers formed at the sidewalls of the gate stack, and an interlayer dielectric layer covering the source region and the drain region, wherein said gate stack comprises a gate dielectric layer that covers the inner wall of the sidewall spacers, and a metal gate on the gate dielectric layer. The semiconductor device further comprises an ion-implanted region in the substrate under the gate stack. The ion-implanted region is used to form a retrograde well.

In the present invention, an ion-implanted region is formed in the substrate directly below a dummy gate by performing ion implantation from the opening formed by removing the dummy gate, such that the profile of the ion-implanted region does not overlap with the dopants of the source/drain regions. In particular, when the step of forming the ion-implanted region is used to form a retrograde well, the present invention can reduce the increase of the band-to-band leakage current and the source-drain junction capacitance in a MOSFET device caused by the introduction of the retrograde well, thereby improving the performance of the device.

### BRIEF DESCRIPTION OF THE DRAWINGS

FIG. 1 is a flow chart illustrating the fabrication method of the semiconductor device according to a first embodiment of the present invention;

FIGS. 2-10 schematically illustrate the respective stages in the fabrication of the semiconductor device according to the first embodiment of the present invention;

FIGS. 11-12 schematically illustrate the respective stages in the fabrication of the semiconductor device according to a second embodiment of the present invention;

FIG. 13 is a flow chart illustrating the fabrication method of the semiconductor device according to the second embodiment of the present invention.

### DETAILED DESCRIPTION OF THE INVENTION

The present invention generally relates to a fabrication method of a semiconductor device, in particular to a semiconductor device that avoids introduction of inappropriate dopants into the source and drain regions from the retrograde well region, as well as the fabrication method thereof. The following disclosure provides many different embodiments or examples for realizing different structures of the present invention. To simplify the disclosure of the present invention, the components and configuration of specific examples are described in the following. Of course, they are merely examples and are not intended to limit the invention. In addition, reference numerals and/or letters can be repeated in different examples in the present invention, and such repetition is for the purpose of concision and clarity, which in itself does not indicate the relationship between the various embodiments and/or configurations. Furthermore, the present invention provides examples of various specific processes and materials, but those skilled in the art will be aware of the applicability of other processes and/or materials. Moreover, the structure in which the first element is “above” the second element as described below may include the embodiment where the first and second elements are formed to be in direct contact, or it may also include the embodiment where a further element is formed between the first and second elements, in which case the first and second elements may not be in direct contact.

### First Embodiment

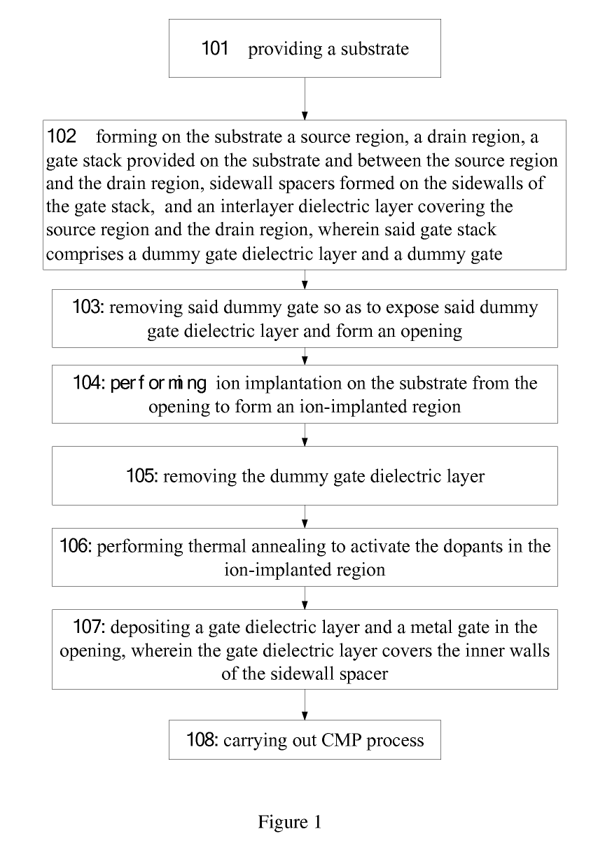

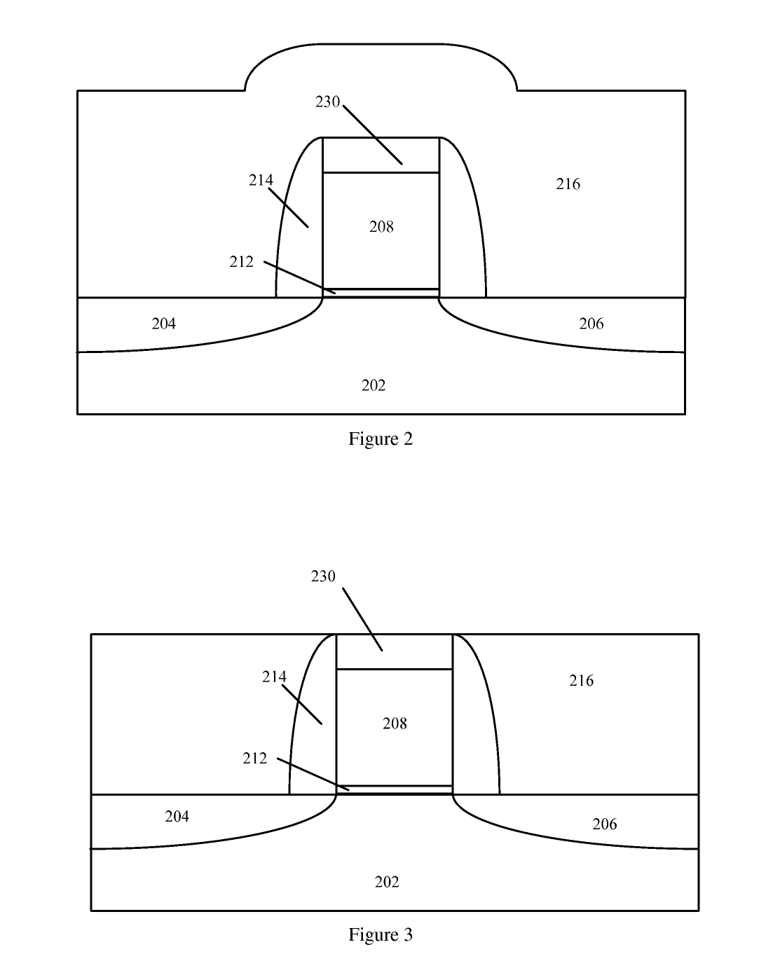

The first embodiment of the present invention is described with reference to FIG. 1. FIG. 1 shows a flow chart of the fabrication method of the semiconductor device according to the embodiment of the present invention. In step 101, a semiconductor substrate 202 is provided first, as shown in FIG. 2. In this embodiment, the substrate 202 comprises a silicon substrate (e.g. a wafer) provided in a crystal structure. According to the design requirements known in the prior art (e.g. a p-type substrate or an n-type substrate), the substrate 202 may comprise various doping configurations. The substrate 202 in other examples may also comprise other basic semiconductor, such as germanium or diamond. Alternatively, the substrate 202 may comprise a compound semiconductor, such as silicon carbide, gallium arsenide, indium arsenide or indium phosphide. In addition, the substrate 202 may optionally comprise an epitaxial layer of which the performance can be enhanced by stress alternation, and may comprise a Silicon-On-Insulator (SOI) structure.

In step 102, a source region 204, a drain region 206, a gate stack 30 and sidewall spacers 214 are formed on the substrate 202, wherein the gate stack 30 is disposed on the substrate and between the source region 204 and the drain region 206, and the sidewall spacers 214 are formed on the side surfaces of the gate stack 30. The gate stack 30 comprises a dummy gate dielectric layer 212 and a dummy gate 208.

The dummy gate dielectric layer 212 may be a thermal oxidation layer, including silicon oxide and silicon nitride, such as silicon dioxide. The dummy gate 208 is a sacrificial layer. The dummy gate 208 may be, for example, polysilicon. In one embodiment, the dummy gate 208 comprises amorphous silicon. The dummy gate dielectric layer 212 and the dummy gate 208 may be formed by MOS (Metal Oxide Semiconductor) processes, such as deposition, photolithography, etching and/or other appropriate methods.

The source/drain regions 204, 206 may be formed by implanting p-type or n-type dopants or impurities to the substrate 202 according to the desired transistor structure. The source/drain regions 204, 206 may also be formed by a method selected from a group comprising photolithography, ion implantation, diffusion and/or other appropriate techniques. The source and drain 204, 206 can be formed after forming the dummy gate dielectric layer 212. The device is thermally annealed by means of conventional semiconductor processing techniques and steps to activate the dopants in the source and drain 204, 206. The thermal annealing may be performed by means of techniques known to those skilled in the art, such as rapid thermal anneal, spike anneal, etc.

The sidewall spacers 214 is formed covering the gate stack 30. The sidewall spacers 214 may be formed of silicon nitride, silicon oxide, silicon oxynitride, silicon carbide, fluoride doped silica glass, or low-k dielectric materials, or any combination thereof, and/or other appropriate materials. The sidewall spacers 214 may have a multi-layered structure. The sidewall spacers 214 may be formed by methods including depositing an appropriate dielectric material. The sidewall spacers 214 has a section thereof covering the gate stack 30, and such a structure can be obtained by techniques known to those skilled in the art. In other embodiments, the sidewall spacers 214 may also not cover the gate stack 30.

Particularly, an interlayer dielectric (ILD) layer 216 may also be formed on the substrate by deposition, which can be, but not limited to, for example undoped silicon oxide (SiO₂), doped silicon oxide (e.g. borosilicate glass, borophosphosilicate glass, etc.) or silicon nitride (Si₃N₄). Said interlayer dielectric layer 216 may be formed by means of Chemical Vapor Deposition (CVD), Physical Vapor Deposition (PVD), Atom Layer Deposition (ALD) and/or other appropriate techniques. The interlayer dielectric layer 216 may have a multi-layered structure. In one embodiment, the interlayer dielectric layer 216 has a thickness ranging from about 30 to 90 nm.

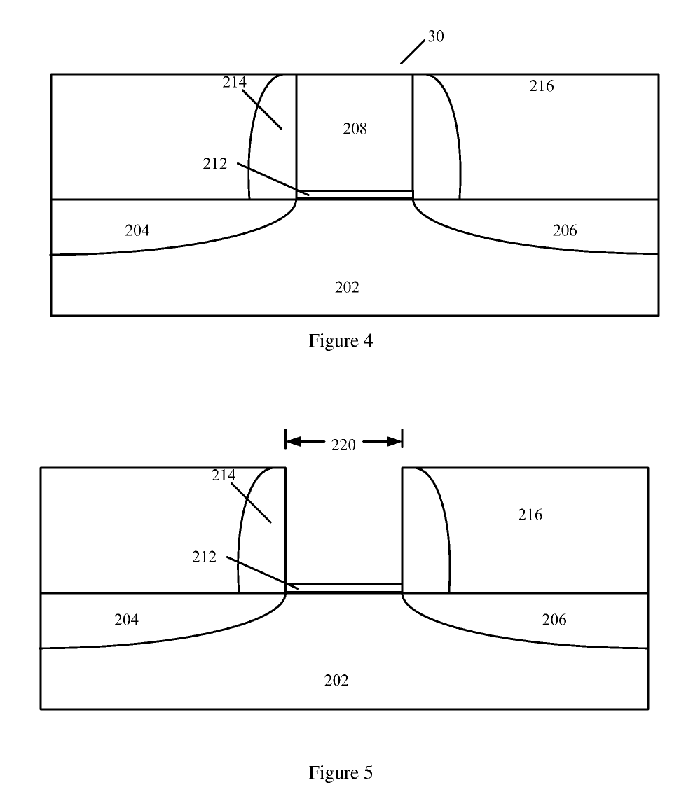

Then, the interlayer dielectric layer 216 and the sidewall spacers 214 are planarized to expose the upper surface of the dummy gate 208. For example, the interlayer dielectric layer 216 can be removed by means of Chemical-Mechanical Polishing (CMP) until the upper surface of the sidewall 214 is exposed, as shown in FIG. 3. After that, Chemical-Mechanical Polishing or Reactive Ion Etching is performed on the sidewall spacers 214 so as to remove the upper surface thereof, thereby exposing the dummy gate 208, as shown in FIG. 4.

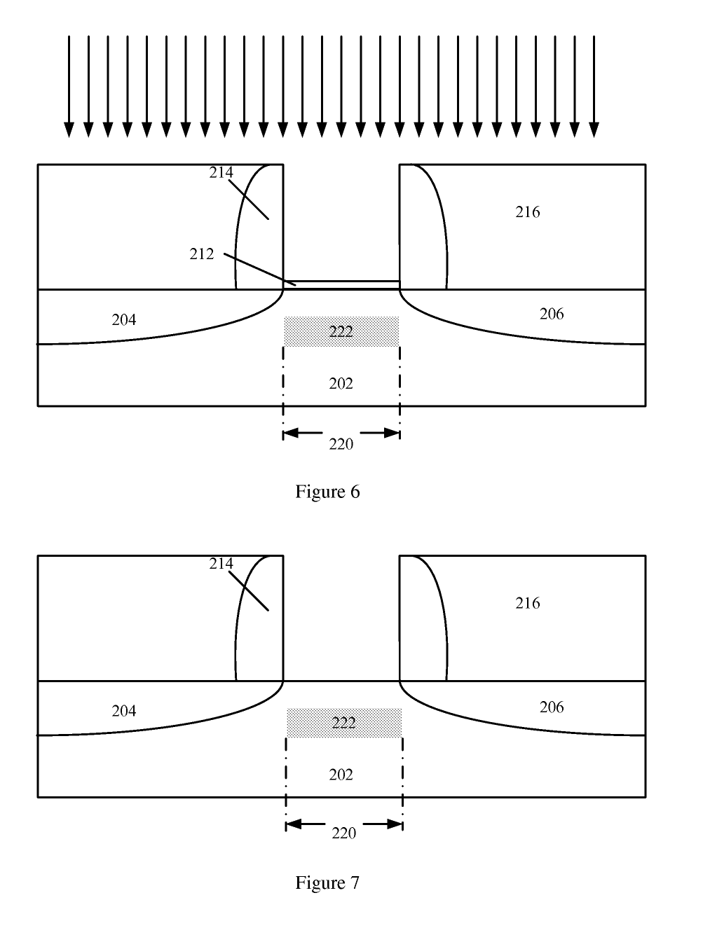

The method then proceeds to step 103, in which the dummy gate 208 is removed so that an opening 220 is formed and the dummy gate dielectric layer 212 is exposed, as shown in FIG. 5. For example, the dummy gate 208 is removed and thus the opening 220 is formed by selectively etching the polysilicon to stop at the dummy gate dielectric layer 212. The dummy gate 208 can be removed by using wet etching and/or dry etching. In one embodiment, the wet etching technique uses tetra methyl ammonium hydroxid (TMAH), potassium hydroxide (KOH) or other appropriate etchant solution.

Afterwards, the method proceeds to step 104, in which the substrate is ion-implanted from the opening 220 to form an retrograde ion-implanted region. Preferably, the ion implantation is a substantially vertical ion implantation. The forming of the ion-implanted region 222 can be used to form a retrograde well, as shown in FIG. 6. With respect to an N-type semiconductor device, elements of group III, such as boron, boron bifluoride or indium, can be used for the ion implantation. With respect to a P-type semiconductor device, elements of group V, such as arsenic or phosphor, can be used for the ion implantation. An energy ranging from about 3 keV to about 40 keV and a dose ranging from about 1e13 to about 1e14 can be used for the ion implantation. When the ion implantation is used to form the retrograde well region, the depth of the implantation ranges from about 10 nm to about 35 nm. The ion implanted retrograde well region 222 is formed in the substrate directly below the opening 220. Since a substantially vertical ion implantation is performed in the opening, the formed ion-implanted region or retrograde well do not overlap with the source region or the drain region.

In step 105, as shown in FIG. 7, the dummy gate dielectric layer 212 is removed, for example, by wet etching and/or dry etching. In one embodiment, the wet etching technique uses hydrofluoric acid (HF) or other appropriate etchant solution. Since the performance of the gate dielectric layer might deteriorate during the ion implantation, the dummy gate dielectric layer 212 needs to be removed and a new gate dielectric layer will be formed later. In this embodiment, the dummy gate dielectric layer 212 is removed after the ion implantation. In other embodiments, the dummy gate dielectric layer 212 may be removed after the thermal annealing of the device in the next step.

Subsequently, in step 106, thermal annealing is performed on the device to activate the dopants (impurities) in the ion-implanted region 222. For example, laser annealing or flash annealing can be employed, and in other embodiments, other thermal annealing techniques can be employed. In this step, the needs for activation of and the influence of diffusion of the dopants (impurities) in the source/drain regions and the source/drain extension regions have to be considered. If the dopants of the source/drain regions and the source/drain extension regions have been activated by thermal annealing, the thermal annealing employed in this step needs to be an instant annealing to reduce diffusion of the dopants in the source/drain regions and the source/drain extension regions. According to the embodiment of the present invention, an instant annealing technique is usually employed for thermal annealing of the device. For example, a microsecond laser annealing is performed at a temperature over about 1300° C.

In step 107, a new gate dielectric layer 224 and a new metal gate 226 are formed in the opening 220, with the gate dielectric layer 224 covering the substrate 202 and the inner walls of the sidewall spacers 214.

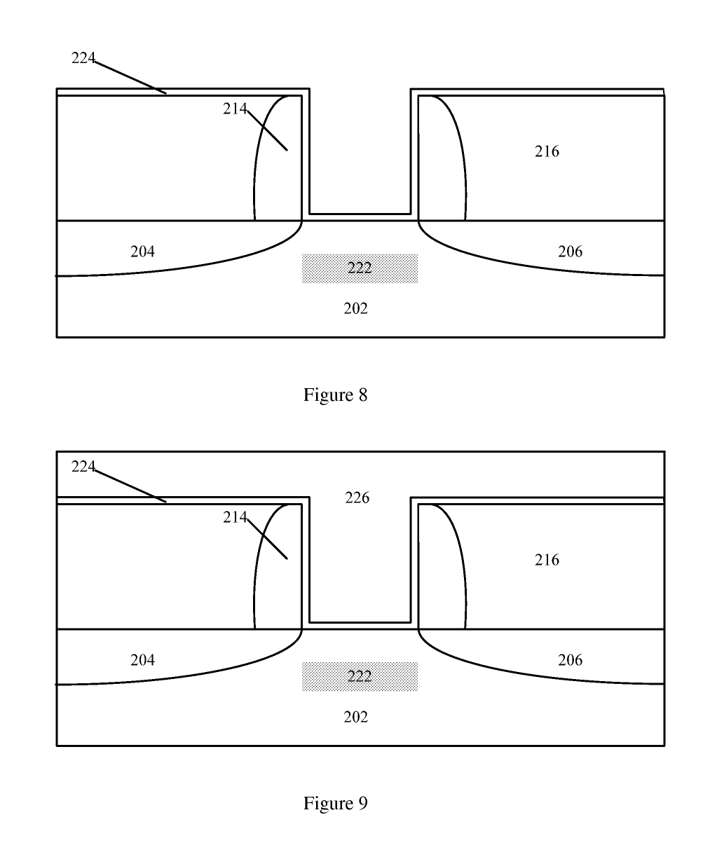

As shown in FIG. 8, the gate dielectric layer 224 is deposited on the surface of the dielectric layer 216 and in the opening, and the gate dielectric layer 224 is a high dielectric constant (high-k) material. In one embodiment, the high-k material comprises hafnium oxide (HfO₂). The high-k material in other examples comprises HfSiO, HfSiON, HfTaO, HfSiO, HfZrO and any combination thereof, and/or other appropriate materials. The gate dielectric layer 224 may have a thickness within the range of about 12 angstroms to 35 angstroms. The gate dielectric layer 212 may be formed by such techniques as Chemical Vapor Deposition (CVD) or Atom Layer Deposition (ALD). The gate dielectric layer 224 may also have a multi-layered structure that includes more than one layers of the above-mentioned materials.

Preferably, after forming the gate dielectric layer 212, a work function metal gate layer may be deposited thereon. The work function metal gate layer may have a thickness within the range of about 10 angstroms to about 100 angstroms. Materials for the work function metal gate layer may include TiN, TiAlN, TaN and TaAlN.

In other embodiments, after forming the new gate dielectric layer 224, a further thermal annealing may be performed to improve the quality of the gate dielectric layer 224. The temperature for the further thermal annealing is in the range of about 600-800° C.

Then, a metal gate 226 is formed on the gate dielectric layer 224, as shown in FIG. 9. The material of the metal gate 226 may include one or more material layers, such as a liner, a material for providing an appropriate work function to the gate, a gate electrode material and/or other appropriate materials. With respect to an N-type semiconductor device, one or more elements selected from the group comprising TiN, TiAlN, TaAlN, TaN, TaSiN, HfSiN, MoSiN, RuTaₓ, NiTaₓ and any combination thereof may be deposited. With respect to a P-type semiconductor device, one or more elements selected from the group comprising TiN, TiSiN, TiCN, TaAlC, TiAlN, TaN, PtSiₓ, Ni₃Si, Pt, Ru, Ir, Mo, HfRu, RuOₓ and any combination thereof may be deposited.

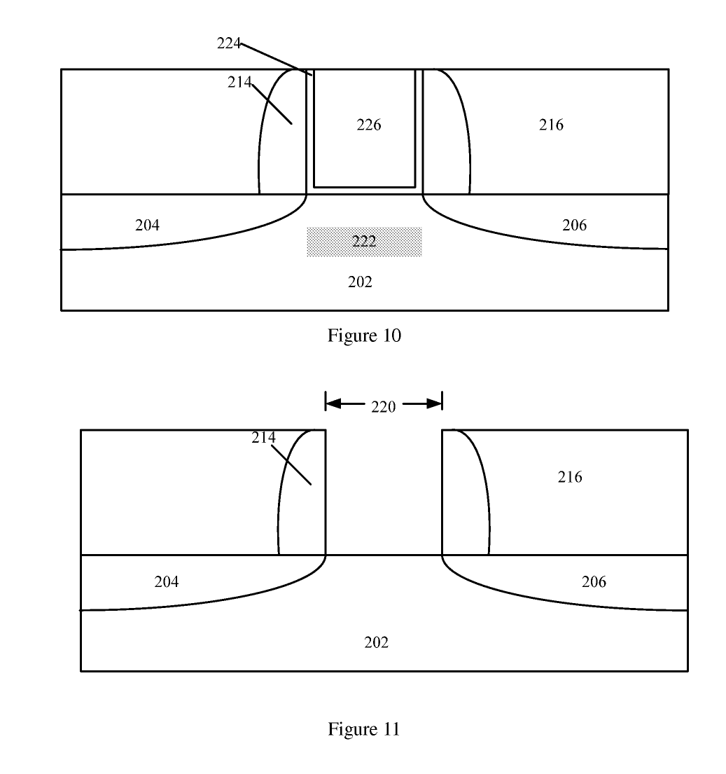

Finally, a Chemical-Mechanical Polishing (CMP) technique is performed to form a metal gate 226, as shown in FIG. 10. The device as shown is a semiconductor device that has the ion-implanted region 222 in the substrate directly below the opening.

### Second Embodiment

The following will only illustrate the aspects of the second embodiment that are different from the first embodiment. The parts that are not illustrated here should be considered as being implemented by using the same steps, methods or techniques as those used in the first embodiment, and are therefore not repeatedly described hereinafter.

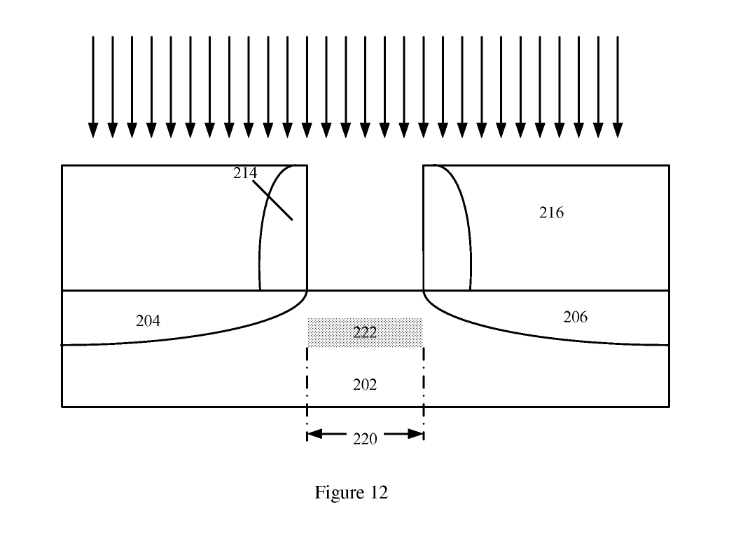

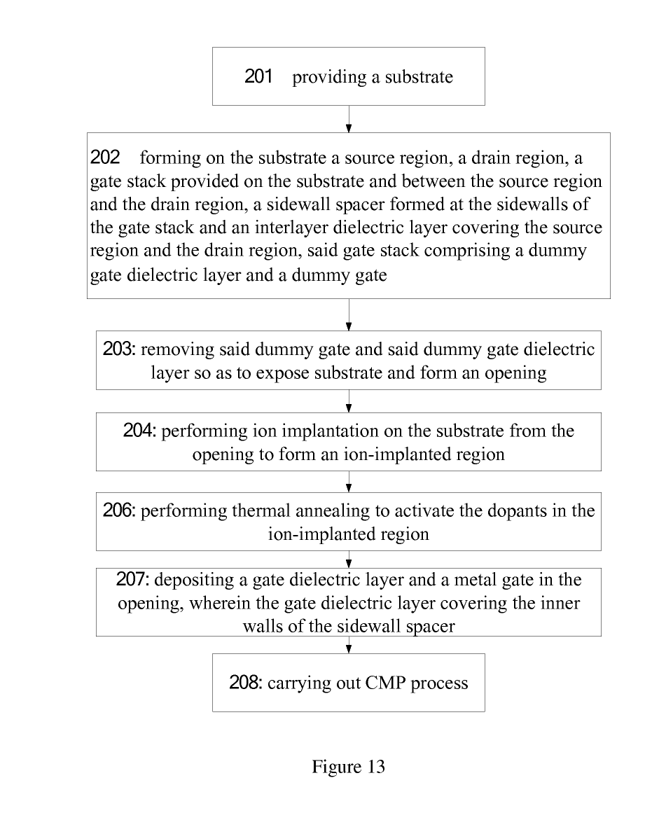

In the second embodiment according to the present invention, as shown in FIG. 13, in step 203, the dummy gate dielectric layer 212 may be removed together with the dummy gate 208 so as to expose the substrate 202 and to form the opening 220, as shown in FIG. 11. The dummy gate 208 and the dummy gate dielectric layer 212 may be removed by means of wet etching and/or dry etching.

Then as in the steps of the first embodiment, ion implantation is performed on the device in step 204 to form an ion-implanted region 222. Preferably, the ion implantation is a substantially vertical ion implantation. The forming of the ion-implanted region 222 can be used to form a retrograde well, as shown in FIG. 12. With respect to an N-type semiconductor device, elements of group III, such as boron, boron bifluoride and indium, are used for the ion implantation. With respect to a P-type semiconductor device, elements of group V, such as arsenic and phosphor, are used for the ion implantation. An energy ranging from about 3 keV to about 40 keV and a dose ranging from about 1e13 to about 1e14 can be used for the ion implantation. When the ion implantation is used to form the retrograde well region, the depth of the implantation ranges from about 10 nm to about 35 nm. The ion-implanted region 222 is formed in the substrate directly below the opening 220. Since a substantially vertical ion implantation is performed in the opening, the formed retrograde well does not overlap with the source region or the drain region.

Since the dummy gate dielectric layer 212 has been removed in step 203, the method proceeds directly to step 206, in which thermal annealing is performed on the device to activate the dopants in the retrograde well 222. For example, laser annealing or flash annealing may be employed, and other thermal annealing techniques may be employed in other embodiments. In this step, the needs for activation of and the influence of diffusion of the dopants (impurities) in the source/drain regions and the source/drain extension regions have to be considered. If the dopants of the source/drain regions and the source/drain extension regions have been activated by annealing, the thermal annealing employed in this step needs to be an instant annealing to reduce diffusion of the dopants in the source/drain regions and the source/drain extension regions. According to the embodiment of the present invention, an instant annealing technique is usually employed for thermal annealing of the device, for example, a microsecond laser annealing is performed at a temperature over about 1300° C.

Afterwards, a new gate dielectric layer 224 and a new metal gate 226 are formed in the opening 220, with the gate dielectric layer 224 covering the substrate 202 and the inner walls of the sidewall spacers 214. Thus, as in the first embodiment, a semiconductor device having an ion-implanted region 222 in the substrate directly below the opening is obtained.

The implementation of the method for fabricating a semiconductor device has been described hereinbefore according to the first and second embodiments of the present invention, which avoids inappropriate introduction of dopants into the source/drain regions when forming an ion-implanted region, such as a retrograde well region, in the substrate.

The embodiments of the present invention performs ion implantation in the opening formed by removing the dummy gate, such that the ion-implanted retrograde well region is formed in the substrate directly below the dummy gate and the profile of the ion-implanted region of the retrograde well does not overlap with the dopants of the source/drain regions. As will be appreciated by those skilled in the art, the formation of the ion-implanted region as mentioned in this description is a conventional ion implantation technique rather than being limited to the formation of a retrograde well, and it can be extended to a conventional ion implantation technique of performing ion implantation in the opening formed by removing the dummy gate and forming an ion-implanted region in the substrate directly below the gate while avoiding performing the ion implantation on the source/drain regions. Any ion-implantable element may use said technique for a specific application.

In addition, the solution of using the retrograde well to reduce the short channel effect in the prior art is based on the idea of forming an steep retrograde well in the channel to reduce the thickness of the depletion layer under the gate and thus reduce the short channel effect. This usually requires the retrograde well to have a very steep profile so as to achieve a better effect. However, due to a large heat budget for thermal annealing of the source region and the drain region, the temperature and time needed for forming atom diffusion by such thermal annealing are greater than those needed for annealing of dopants in the channel region, adversely resulting in a too large diffusion of the dopant atoms in the channel region, which damages the steep doping profile. The process of the present invention may choose to perform thermal annealing of the source/drain regions and form the retrograde well in the channel region before performing thermal annealing of the retrograde well, so it avoids the influence to the retrograde well by the thermal annealing of the source/drain regions, and advantageously avoids damage of the profile of the steep retrograde well.

Furthermore, since the ion implantation for forming the retrograde well in the substrate is usually performed after forming the gate dielectric, the ion implantation may cause deterioration of the gate dielectric and thus adversely degrade performance of the device. The present invention performs ion implantation to the retrograde well first, and then forms the gate dielectric and the metal gate, thus avoiding the problem of deterioration of the gate dielectric as mentioned above.

Although the example embodiments and the advantages thereof have been described in detail, it shall be understood that various changes, substitutions and modifications can be made to said embodiments without departing from the spirit of the invention and the scope defined by the appended claims. As for other examples, those ordinarily skilled in the art shall easily understand that the sequence of the process steps may be changed without departing from the scope of the present invention.

In addition, the application of the present invention is not limited to the techniques, mechanisms, fabrication, compositions, means, methods and steps in the specific embodiments described in the description. On the basis of the disclosure of the present invention, those ordinarily skilled in the art shall easily understand that the existing or to be developed techniques, mechanisms, fabrication, compositions, means, methods and steps, which have substantially the same function or achieve substantially the same effect as the respective embodiments described in the present invention, can also be used according to the present invention. Therefore, the appended claims intend to include such techniques, mechanisms, fabrication, compositions, means, methods and steps in the scope thereof.

1. A method for fabricating a semiconductor device, comprising the steps of:
a) providing a substrate;
b) forming a source region, a drain region, a gate stack, sidewall spacers, and an interlayer dielectric layer on said substrate, wherein said gate stack is provided on said substrate and between said source region and said drain region, said sidewall spacers are formed at the sidewalls of said gate stack, said interlayer dielectric layer covers said source region and said drain region, and said gate stack comprises a dummy gate dielectric layer and a dummy gate;
c) removing said dummy gate so as to expose said dummy gate dielectric layer and form an opening;
d) performing ion implantation on said substrate from said opening to form an ion-implanted region;
e) removing said dummy gate dielectric layer;
f) performing thermal annealing to activate dopants in said ion-implanted region;
g) depositing a gate dielectric layer and a metal gate in said opening, wherein said gate dielectric layer covers the inner walls of said sidewall spacers.

2. The method according to claim 1, wherein said step e) is carried out after said step f).

3. The method according to claim 1, wherein a thermal anneal is performed prior to said step d) to activate the dopants in said source region and said drain region.

4. The method according to claim 1, wherein said step d) is used to form a retrograde well.

5. The method according to claim 4, wherein said step of forming the retrograde well region comprises: using elements of group III for the ion implantation with respect to an N-type semiconductor device, said elements of group III includes boron, boron bifluoride or indium, the energy of the ion implantation is 3-40 keV, and the dose is 1e13-1e14.

6. The method according to claim 4, wherein said step of forming the retrograde well region comprises: using elements of group V for the ion implantation with respect to a P-type semiconductor device, said elements of group V includes phosphor or arsenic, the energy of the ion implantation is 3-40 keV, and the dose is 1e13-1e14.

7. The method according to claim 4, wherein the depth of said ion implantation ranges from 10 nm to 35 nm.

8. (canceled)

9. The method according to claim 1, wherein the step of performing ion implantation on said substrate from said opening comprises performing substantially vertical ion implantation.

10. The method according to claim 4, wherein said retrograde well is formed in said substrate directly below said opening.

11. The method according to claim 10, wherein said retrograde well does not overlap with said source region or said drain region.

12. A method for fabricating a semiconductor device, comprising the steps of:
a) providing a substrate;
b) forming a source region, a drain region, a gate stack, sidewall spacers, and an interlayer dielectric layer on said substrate, wherein said gate stack is disposed on said substrate and between said source region and said drain region, said sidewall spacers are formed at the sidewalls of said gate stack, said interlayer dielectric layer covers said source region and said drain region, and said gate stack comprises a dummy gate dielectric layer and a dummy gate;
c) removing said dummy gate and said dummy gate dielectric layer so as to expose said substrate and form an opening;
d) performing ion implantation on said substrate from said opening to form an ion-implanted region;
e) performing thermal annealing to activate dopants in said ion-implanted region;
f) depositing a gate dielectric layer and a metal gate in said opening, wherein said gate dielectric layer covers the inner walls of said sidewall spacers.

13. The method according to claim 12, wherein a thermal annealing is performed prior to said step d) to activate the dopants in said source region and said drain region.

14. The method according to claim 12, wherein said step d) is used to form a retrograde well.

15. The method according to claim 14, wherein the step of forming the retrograde well region comprises: using elements of group III for the ion implantation with respect to an N-type semiconductor device, wherein said elements of group III includes boron, boron bifluoride or indium, the energy of the ion implantation is 3-40 keV, and the dose is 1e13-1e14.

16. The method according to claim 14, wherein the step of forming the retrograde well region comprises: using elements of group V for the ion implantation with respect to a P-type semiconductor device, wherein said elements of group V includes phosphor or arsenic, the energy of the ion implantation is 3-40 keV, and the dose is 1e13-1e14.

17. The method according to claim 14, wherein the depth of the ion implantation ranges from 10 nm to 35 nm.

18. (canceled)

19. The method according to claim 12, wherein the step of performing ion implantation on said substrate from said opening comprises performing substantially vertical ion implantation.

20. The method according to claim 14, wherein the retrograde well is formed in said substrate directly below said opening.

21. The method according to claim 20, wherein the retrograde well does not overlap with said source region or said drain region.

22. A semiconductor device, which comprises: a substrate, a source region and a drain region formed on said substrate, a gate stack formed on said substrate and between said source region and said drain region, sidewall spacers formed at the sidewalls of said gate stack, and an interlayer dielectric layer covering said source region and said drain region, wherein said gate stack comprises a gate dielectric layer and a metal gate, said gate dielectric layer covers the inner walls of said sidewall spacers, and said semiconductor device further comprises an ion-implanted region in said substrate below said gate stack.

23. The semiconductor device according to claim 22, wherein said ion-implanted region is used to form a retrograde well.

24. The semiconductor device according to claim 23, wherein said gate dielectric layer and said metal gate are formed after forming said retrograde well and thermal annealing said retrograde well.

25. The semiconductor device according to claim 23, wherein with respect to an N-type semiconductor device, elements of group III are used for the ion implantation to form said retrograde well, said elements of group III including boron, boron bifluoride or indium, the energy of the ion implantation being 3-40 keV, and the dose being 1e13-1e14.

26. The semiconductor device according to claim 23, wherein with respect to a P-type semiconductor device, elements of group V are used for the ion implantation to form said retrograde well, said elements of group V including phosphor or arsenic, the energy of the ion implantation being 3-40 keV, and the dose being 1e13-1e14.

27. The semiconductor device according to claim 23, wherein the depth of said retrograde well ranges from 10 nm to 35 nm.

28. (canceled)

29. The semiconductor device according to claim 22, wherein said ion-implanted region is formed by vertical ion implantation.

30. The semiconductor device according to claim 29, wherein said ion-implanted region does not overlap with said source region or said drain region.
